(19) United States
(12) Patent Application Publication
(10) Pub. No.: US 2024/0202397 A1
(43) Pub. Date: Jun. 20, 2024

(54) METHOD FOR CREATING A CO-SIMULATION

(71) Applicant: dSPACE GmbH, Paderborn (DE)

(72) Inventor: Martin KRONMUELLER, Paderborn (DE)

(21) Appl. No.: 18/544,676

(22) Filed: Dec. 19, 2023

(30) Foreign Application Priority Data
Dec. 20, 2022 (DE) 102022134031.7

(51) Int. Cl. G06F 30/20

(52) U.S. Cl. CPC G06F 30/20

(57) ABSTRACT

A method for creating a co-simulation having a plurality of simulation modules with communications interfaces is provided. The method includes generating simulation components, which are containers for one or more simulation modules. The simulation modules are assigned to the simulation components. Each simulation component is provided with a runtime environment information module. Each simulation component is provided with a communications unit that contains a description of the communications interface of the simulation module, wherein communication with further simulation components is enabled. The communications units of the simulation components are connected to one or more communications units of further simulation components. The co-simulation application is created, in which the simulation components of the simulation component level are assigned to a simulation agent type with the runtime environment information modules of the simulation components.

### CROSS REFERENCE TO RELATED APPLICATIONS

This application claims benefit to German Patent Application No. DE 102022134031.7, filed on Dec. 20, 2022, which is hereby incorporated by reference herein.

### FIELD

The present disclosure relates to a method for creating a co-simulation having a plurality of simulation modules, wherein the simulation modules in each case have at least one communications interface and in each case can be executed with simulation agents, comprising the following method steps: generating simulation components, which in each case are a container for one simulation module or several simulation modules, assigning the simulation modules to the simulation components, providing each simulation component with a runtime environment information module that has information on the requirements of the simulation modules contained in the simulation component for the runtime environment, wherein the respective simulation agents may have properties corresponding to the requirements of the simulation modules in order to be able to execute them, and providing each simulation component with a communications unit that contains a description of the communications interface of the simulation module, such that communication with further simulation components is enabled.

### BACKGROUND

There are a variety of simulation tools for creating model-in-the-loop, software-in-the-loop, hardware-in-the-loop, or connected-mixed-reality simulations. A simulation tool usually consists of an editor, which can be used to define what is to be simulated, and a compiler, a just-in-time compiler, or an interpreter in a simulation environment. The simulation defined in the editor can be executed with the compiler, the just-in-time compiler, or the interpreter. Each of these simulation tools is typically designed for special areas of application. Connected mixed-reality simulations are mixed simulations of real and simulated control units.

A simulation tool that has been developed on a computing unit is a simulation agent. The computing unit does not necessarily have to be a localizable computing unit. Rather, this computing unit can be part of a computing cluster or part of a cloud computing solution. The individual simulation is a simulation module executed with the simulation agent, wherein the simulation module can be a script that can be ported into the editor of a simulation tool. A script is a file that can be implemented with the simulation agent and can also be in binary format. If necessary, an executable can be generated from the simulation module prior to execution. The executable is a compiled script and therefore a program that can be executed on a processor.

A co-simulation is characterized by the fact that it contains several simulation modules, which can be variously designed and can require similar, but also different types of simulation agents for execution. In order to create a co-simulation with various simulation modules and the associated simulation agents, the simulation modules or the specific simulation environments of the simulation tools of the simulation agents may be modified in such a way that data can be exchanged between the simulation modules via special bus systems. This communication may be realized within the individual simulation tools and therefore in different ways in each case. In addition to the communication between the simulation modules, a consistent distribution of the simulation modules to the different simulation environments, a time synchronization, and a control of the simulations are to be realized.

The Functional Mock-up Interface specification defines a standard that describes containers that can accommodate simulation modules. These containers are provided with interface descriptions for communication. Accordingly, the communication of the simulation modules assigned to simulation components and the type of data exchanged is defined exclusively within the associated simulation agents and is thus not universally valid. It follows that the execution of a simulation module on different simulation agents requires a new adjustment of the communication in each case, and that changes to the simulation regarding the model-in-the-loop, software-in-the-loop, hardware-in-the-loop, or connected mixed-reality simulation type result in communication changes, which in turn require time-consuming adjustments to the communication of the simulation modules. Thus, every change in the simulation modules or in the simulation type requires a further adjusted, memory-intensive co-simulation. The distribution of a simulation model to various simulation environments may also be specific to the simulation environment.

### SUMMARY

In an embodiment, the present disclosure provides a method for creating a co-simulation having a plurality of simulation modules. The simulation modules in each case have at least one communications interface, and in each case are configured to be executed with simulation agents. the method includes:
S1) generating simulation components, which in each case are a container for one simulation module or several simulation modules of the simulation modules;
S2) assigning the simulation modules to the simulation components;
S3) providing each simulation component, of the simulation components, with a respective runtime environment information module, wherein the respective runtime environment information module comprises information on requirements of the simulation modules contained in the simulation component for the runtime environment, wherein the respective simulation agents have properties corresponding to the requirements of the simulation modules in order to be able to execute the simulation modules;
S4) providing each simulation component with a communications unit that contains a description of the communications interface of the simulation module, such that communication with further simulation components is enabled,
S5) connecting the communications units of the simulation components to one or more communications units of further simulation components, such that a network of the simulation components connected to one another via the communications units is formed, wherein the network of simulation components forms a simulation component level that is independent of the physical requirements for the runtime environment, but the information on the requirements for executing the simulation component level is contained in the runtime environment information modules; and
S6) creating a co-simulation application in which the simulation components of the simulation component level are assigned to a simulation agent type with the runtime environment information modules of the simulation components, wherein the simulation agent type is a description of the properties of the simulation agent required to execute the simulation module.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 a flowchart for a method according to an exemplary embodiment of the present disclosure;

FIG. 2 schematically, a simulation component according to an exemplary embodiment of the present disclosure; and

FIG. 3 schematically, a co-simulation according to an exemplary embodiment of the present disclosure.

### DETAILED DESCRIPTION

In view of the background discussed above, aspects of the present disclosure provide a time-efficient and memory-efficient method for creating a co-simulation.

According to the present disclosure, a method for creating a co-simulation having a plurality of simulation modules is thus provided, wherein the simulation modules in each case have at least one communications interface and in each case can be executed with simulation agents, comprising the following method steps:
Generating simulation components, which in each case are a container for one simulation module or several simulation modules;
Assigning the simulation modules to the simulation components;
Providing each simulation component with a runtime environment information module that contains information on the requirements of the simulation modules contained in the simulation component for the runtime environment, wherein the respective simulation agents may have properties corresponding to the requirements of the simulation modules in order to be able to execute them;
Providing each simulation component with a communications unit that contains a description of the communications interface of the simulation module, such that communication with further simulation components is enabled;
Connecting the communications units of the simulation components to one or more communications units of further simulation components, such that a network of the simulation components connected to one another via the communications units is formed, wherein this network of simulation components forms a simulation component layer that is independent of the physical requirements for the runtime environment, but the information on the requirements for executing the simulation component layer is contained in the runtime environment information modules; and
Creating a co-simulation application in which the simulation components of the simulation component level are assigned to a simulation agent type with the runtime environment information modules of the simulation components, wherein the simulation agent type is a description of the properties of the simulation agent required to execute the simulation module.

This provides a method for creating a co-simulation that is significantly more time-efficient and memory-efficient than conventional methods. With the present disclosure, the existing computer hardware can thus be used substantially more efficiently than before by the improvement in internal computer processes.

The smallest unit of a co-simulation is the individual simulation module. Each simulation module has requirements for its runtime environment. In this respect, a simulation tool that can be used for co-simulation is part of these requirements. The requirements can also in any event relate to the processor architecture, the number of available CPU's and GPU's, the RAM, or the operating system. In addition to the further requirements, the simulation tool is designed as a property on a simulation agent that can execute the simulation module.

The simulation module is assigned to a simulation component that is equipped with a communications unit and a runtime environment information module. The communications unit contains a description of the communications interface of the simulation module. This allows the type of communication with further simulation components to be defined. The types of communication possible in the communications interface are independent of specific simulation agents and can be signal-based communication in the form of model port connections or a bus access request in the form of an automotive bus such as Ethernet, CAN, Lin, or FlexRay. The physical bus does not necessarily have to be provided in every simulation component. Instead, the physical bus for a simulation component can be provided by another simulation component. In the context of a software-in-the-loop simulation type, a physical bus is therefore not necessarily required. Rather, direct communication with a further simulation component can also be established with a virtual bus. In addition, data exchange can be enabled via a global data structure that is synchronized between the simulation agents, and via inputs and outputs in the form of electrical signals that connect the simulation components with one another.

The runtime environment information modules of the simulation components show the requirements, needed to execute the simulation module, for the runtime environment. The requirements for the runtime environment include the minimum requirements that a simulation agent may have as properties in order to be able to execute the corresponding simulation component. This also includes necessary connections with other simulation agents, in interdependent simulation components, or simulation components that are mutually dependent.

By creating a co-simulation application, a hierarchy is generated, with which the co-simulation application can be orchestrated. Here, orchestrating a co-simulation application specifically means executing certain simulation modules, contained in the simulation components, in a certain sequence.

According to a further development of the present disclosure, it is provided that the simulation agents be configured to be able to execute hardware-in-the-loop, software-in-the-loop, or model-in-the-loop simulations. The combination of simulation components forms the simulation component level. This is independent of the subsequent execution of the co-simulation application and, in particular, the type of simulation. Model-in-the-loop, software-in-the-loop, hardware-in-the-loop, or connected-mixed-reality simulations can be executed in this way with the same, unchanged simulation component level. Version updates of the simulation component level or the simulation agents can be carried out independently of one another and do not affect the respective other structure.

According to a further development of the present disclosure, the method comprises the following further method steps: grouping simulation components with runtime environment information modules having compatible requirements, categorizing the simulation components with runtime environment information modules having compatible requirements in a processing unit application, such that simulation components with runtime environment information modules having compatible requirements are arranged in a common processing unit application, and simulation components with runtime environment information modules having incompatible requirements are arranged in different processing unit applications. Simulation components with compatible requirements in the runtime environment information modules can be executed together with a simulation agent type that has the corresponding description of the properties. Execution can take place chronologically, in parallel, and under real-time conditions. It is not necessary for the runtime environment information modules of the simulation components to have the same number of identical or compatible requirements for the runtime environment. If necessary, it is sufficient that the requirements for the runtime environment of the simulation component that has the most requirements are fulfilled.

In a further embodiment of the present disclosure, the method comprises the following further steps: forming a simulation inventory that contains simulation agent types available in a simulation agent type network, and selecting the simulation agent types, required for executing the processing unit application, from the simulation inventory. The available simulation agent types are those simulation agent types that are available for executing the co-simulation application. The network connections of the simulation agent types describe the connections between the simulation agents described by the respective simulation agent types, such that any communication between the simulation components on different simulation agents can be fulfilled. For example, data can be exchanged via a global data structure that can be synchronized between the simulation agents. A simulation agent type is the description of the properties of the simulation agent required to execute the simulation module. There can be several simulation agents of one simulation agent type in a simulation agent type network.

In principle, the simulation agents can be associated with the co-simulation application in various ways. However, according to an exemplary embodiment of the present disclosure, the method comprises the following further steps: providing a simulation agent inventory that contains the simulation agents corresponding to the simulation agent types, and associating the co-simulation application with the simulation agents. The provision of a simulation agent inventory enables more rapid retrieval of the available simulation agents. Associating the co-simulation application with the simulation agents includes assigning the simulation agents to the respective simulation components. The simulation components can then be executed with the corresponding simulation agents.

In principle, the co-simulation application can be implemented in various ways. According to an exemplary embodiment, however, it is provided that the co-simulation application be executed in parallel on a computing cluster. Several instances of this co-simulation application can thus be executed in parallel on the computing cluster. The entire co-simulation application does not necessarily have to be executed on a computing cluster. In the case of co-simulation applications that execute hardware-in-the-loop simulations, the co-simulation application may be only partially executed on a computing cluster. The part of the co-simulation application that concerns the hardware can then be executed on a specialized workstation with the corresponding linked hardware. Here, a workstation means a local computing unit. In this specific example, the hardware together with the computing unit are the simulation agent.

According to a further development of the present disclosure, it is provided that the co-simulation application be executed in parallel on a GPU architecture of the computing cluster. The execution of the co-simulation application on a GPU architecture enables particularly rapid and efficient calculation. In a further embodiment of the present disclosure, several instances of the co-simulation application are generated. With a plurality of available simulation agents of the simulation agent types required to execute the co-simulation application, better utilization and thus more efficient use of the hardware can be achieved. The instances of the co-simulation application can be distributed to various available simulation agents, and further co-simulation applications can thus also be dynamically allocated. This enables the prioritization of individual parts of the co-simulation application or other co-simulation applications.

It is possible for the simulation agents to be formed on a local computing unit. However, according to an exemplary embodiment, it is provided that the simulation agents be part of a cloud computing system, and the co-simulation application be ported to this cloud computing system. Parts of the co-simulation application that are not hardware-bound can be executed in a decentralized manner in a cloud computing environment, such that the executability of the co-simulation application is not tied to the resources of a user and can also be made available as a service.

According to the present disclosure, there is further provided a non-volatile, computer-readable storage medium with instructions stored thereon that, when executed on a processor, effect a method according to one of the preceding claims.

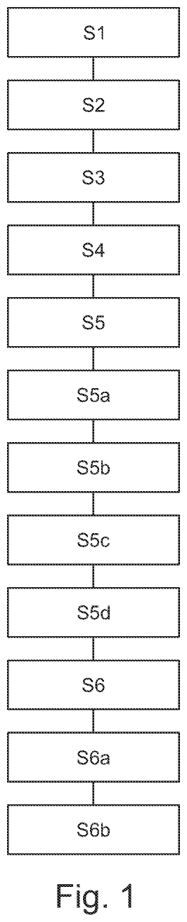

FIG. 1 shows a flowchart for a method according to an exemplary embodiment of the present disclosure. This method comprises steps S1 through S6b.

This method for creating a co-simulation 100 having several simulation modules 1 with communications interfaces 2, wherein the simulation modules 1 are executable with simulation agents 4, comprises the following steps:
S1) Generating simulation components 6, which are containers for one or more simulation modules;
S2) Assigning the simulation modules 1 to the simulation components 6;
S3) Providing each simulation component 6 with a runtime environment information module 8 that has information on the requirements of the simulation modules 1 contained in the simulation component 6 for the runtime environment, wherein the respective simulation agents 4 may have properties corresponding to the requirements of the simulation modules 1 in order to be able to execute them,;
S4) Providing each simulation component 6 with a communications unit 10 that contains a description of the communications interface 2 of the simulation module 1, such that communication with further simulation components 6 is enabled;
S5) Connecting the communications units 10 of the simulation components 6 to one or more communications units 10 of further simulation components 6, such that a network of the simulation components 6 connected to one another via the communications units 10 is formed, wherein this network of simulation components 6 forms a simulation component level 12 that is independent of the physical requirements for the runtime environment, but the information on the requirements for executing the simulation component level 12 is contained in the runtime environment information modules 8;
S5a) Grouping simulation components 6 with runtime environment information modules 8 having compatible requirements;
S5b) Categorizing the simulation components 6 with runtime environment information modules 8 having compatible requirements in a processing unit application 14, such that simulation components 6 having runtime environment information modules 8 having compatible requirements are arranged in a processing unit application 14, and simulation components 6 with runtime environment information modules 8 having incompatible requirements are arranged in different processing unit applications 14;
S5c) Forming a simulation inventory that contains the simulation agent types 16 available in a simulation agent type network;
S5d) Selecting the simulation agent types 16, required for executing the processing unit application 14, from the simulation inventory;
S6) Creating the co-simulation application 18 in which the simulation components 6 of the simulation component level 12 are assigned to a simulation agent type 16 with the runtime environment information modules 8 of the simulation components 6, wherein the simulation agent type 16 is a description of the properties of the simulation agent 4 required to execute the simulation module 1;
S6a) Providing a simulation agent inventory that contains the simulation agents 4 corresponding to the simulation agent types 16; and
S6b) Associating the co-simulation application 18 with the simulation agents 4.

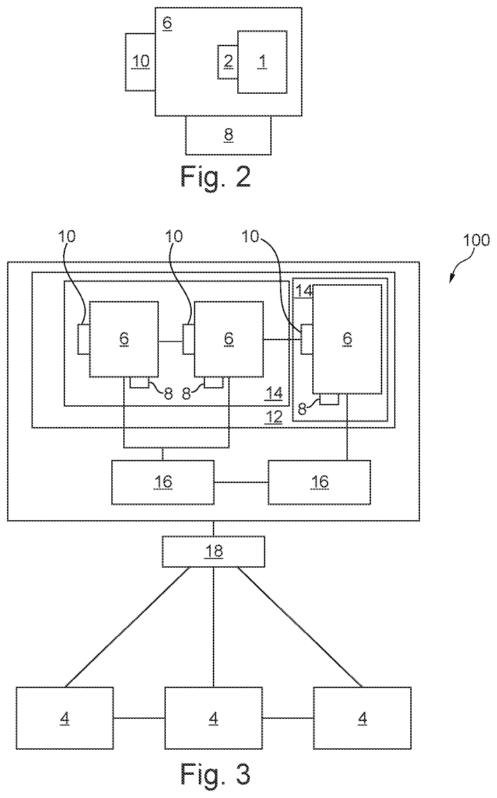

FIG. 2 schematically shows the simulation component 6 according to the present disclosure. The simulation component 6 is formed with the runtime environment information module 8 and the communications unit 10. The communications unit 10 contains a description of the communications interface 2, accommodated in the simulation component 6, of the simulation module 1. The simulation module 1 can be a script. A script is a file that can be implemented with the simulation agent 4 and can also be in binary format. If necessary, an executable can be generated from simulation module 1 prior to execution.

Finally, FIG. 3 schematically shows a co-simulation 100 according to an exemplary embodiment of the present disclosure. The simulation components 6 are assigned according to their requirements for the runtime environment to the processing unit applications 14. The communications units 10 of the simulation components 6 are connected to one another, and the simulation components 6 form the simulation component level 12. This is independent of the physical requirements for the runtime environment. However, the requirements for executing the simulation component level 12 with the respective simulation agents 4 are contained in the runtime environment information modules 8. The simulation agent types 16 available in a simulation agent type network are listed in the simulation inventory. The simulation agent types 16 required to execute the co-simulation application are then selected from this simulation agent type network. The co-simulation application 18 is created, in which the simulation components 6 of the simulation component level 12 are assigned to a simulation agent type 16 with the runtime environment information modules 8 of the simulation components 6. The simulation agents 4 corresponding to the simulation agent types 16 are contained in the simulation agent inventory provided. The simulation agents 4 can thus be associated with the co-simulation application 18. The simulation agents 4 are connected to one another by a network, such that the execution of the simulation modules 1 contained in the simulation components 6 can be orchestrated with the hierarchy generated by forming a co-simulation application 18. In addition, data can be transferred between the simulation agents 4. In the case of a conditional co-simulation 100 in which, for example, a workstation with hardware is dependent upon the result of a previous simulation to operate this hardware, this is transferred between the simulation agents 4.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

1 Simulation module
2 Communications interface
4 Simulation agent
6 Simulation component
8 Runtime environment information module
10 Communications unit
12 Simulation component level
14 Processing unit application
16 Simulation agent type
18 Co-simulation application
100 Co-simulation

1. A method for creating a co-simulation comprising a plurality of simulation modules, the simulation modules in each case having at least one communications interface, and in each case being configured to be executed with simulation agents, the method comprising:
S1) generating simulation components, which in each case are a container for one simulation module or several simulation modules of the simulation modules;
S2) assigning the simulation modules to the simulation components;
S3) providing each simulation component, of the simulation components, with a respective runtime environment information module, wherein the respective runtime environment information module comprises information on requirements of the simulation modules contained in the simulation component for the runtime environment, wherein the respective simulation agents have properties corresponding to the requirements of the simulation modules in order to be able to execute the simulation modules;
S4) providing each simulation component with a communications unit that contains a description of the communications interface of the simulation module, such that communication with further simulation components is enabled,
S5) connecting the communications units of the simulation components to one or more communications units of further simulation components, such that a network of the simulation components connected to one another via the communications units is formed, wherein the network of simulation components forms a simulation component level that is independent of the physical requirements for the runtime environment, but the information on the requirements for executing the simulation component level is contained in the runtime environment information modules; and
S6) creating a co-simulation application in which the simulation components of the simulation component level are assigned to a simulation agent type with the runtime environment information modules of the simulation components, wherein the simulation agent type is a description of the properties of the simulation agent required to execute the simulation module.

2. The method according to claim 1, wherein the simulation agents are configured to execute hardware-in-the-loop, software-in-the-loop, or model-in-the-loop simulations.

3. The method according to claim 1, further comprising:
S5a) grouping simulation components with runtime environment information modules having compatible requirements; and
S5b) categorizing the simulation components with runtime environment information modules having compatible requirements in a processing unit application, such that simulation components with runtime environment information modules having compatible requirements are arranged in a common processing unit application, and simulation components with runtime environment information modules having incompatible requirements are arranged in different processing unit applications.

4. The method according to claim 3, further comprising:
S5c) forming a simulation inventory that contains the simulation agent types available in a simulation agent type network; and
S5d) selecting the simulation agent types, required for executing the processing unit application, from the simulation inventory.

5. The method according to claim 4, further comprising:
S6a) providing a simulation agent inventory that contains the simulation agents corresponding to the simulation agent types; and
S6b) associating the co-simulation application with the simulation agents.

6. The method according to claim 1, wherein the co-simulation application is executed in parallel on a computing cluster.

7. The method according to claim 6, wherein the co-simulation application is executed in parallel on a GPU architecture of the computing cluster.

8. The method according to claim 1, wherein several instances of the co-simulation application are generated.

9. The method according to claim 1, wherein the simulation agents are part of a cloud computing system, and the co-simulation application is ported to this cloud computing system.

10. A non-transitory, computer-readable storage medium having instructions stored thereon that, when executed on a processor, effect a method for creating a co-simulation comprising a plurality of simulation modules, the simulation modules in each case having at least one communications interface, and in each case being configured to be executed with simulation agents, the method comprising:
S1) generating simulation components, which in each case are a container for one simulation module or several simulation modules of the simulation modules;
S2) assigning the simulation modules to the simulation components;
S3) providing each simulation component, of the simulation components, with a respective runtime environment information module, wherein the respective runtime environment information module comprises information on requirements of the simulation modules contained in the simulation component for the runtime environment, wherein the respective simulation agents have properties corresponding to the requirements of the simulation modules in order to be able to execute the simulation modules;
S4) providing each simulation component with a communications unit that contains a description of the communications interface of the simulation module, such that communication with further simulation components is enabled,
S5) connecting the communications units of the simulation components to one or more communications units of further simulation components, such that a network of the simulation components connected to one another via the communications units is formed, wherein the network of simulation components forms a simulation component level that is independent of the physical requirements for the runtime environment, but the information on the requirements for executing the simulation component level is contained in the runtime environment information modules; and
S6) creating a co-simulation application in which the simulation components of the simulation component level are assigned to a simulation agent type with the runtime environment information modules of the simulation components, wherein the simulation agent type is a description of the properties of the simulation agent required to execute the simulation module.
